(19) United States
(12) Patent Application Publication
(10) Pub. No.: US 2006/0022348 A1
(43) Pub. Date: Feb. 2, 2006

(54) Method of sealing low-k dielectrics and devices made thereby

(76) Inventors: Thomas Joseph Abell, Oud-Heverlee (BE); Jorg Shuhmacher, Grez-Doiceau (BE); Denis Shamiryan, Leuven (BE)

Correspondence Address: INTEL/BLAKELY, 12400 WILSHIRE BOULEVARD, SEVENTH FLOOR, LOS ANGELES, CA, 90025-1030, US

(21) Appl. No.: 11/204,613

(22) Filed: Aug. 15, 2005

Related U.S. Application Data
(62) Division of application No. 10/879,899, filed on Jun. 29, 2004.

(51) Int. Cl. H01L 23/48; H01L 23/52

(52) U.S. Cl. 257/762; 257/774

(57) ABSTRACT

Methods for sealing porous low-k dielectrics, and devices made thereby, are described, comprising treating the porous low-k dielectrics by atomic layer deposition so as to seal the pores. ALD reactants are chosen in part based on their size, such that they do not deeply penetrate the interconnected pore structures of the dielectrics.

This is a Divisional Application of Ser. No. 10/879,899 filed Jun. 29, 2004, which is presently pending.

### FIELD OF THE INVENTION

Methods for the fabrication of electronic devices comprising low-k dielectrics and devices made thereby are described.

### BACKGROUND INFORMATION

Manufacturers of semiconductor devices constantly strive to improve device performance and reduce device size. Performance improvements and device size reduction are frequently pursued by reducing feature sizes, such as interconnect sizes, on the device. Reducing the size of interconnects has led to the implementation of copper interconnects, which exhibit low electrical resistance. Copper interconnects may be implemented in conjunction with low-k dielectrics in order to reduce the coupling capacitance of the interconnects and thereby improve signal integrity.

The implementation of copper interconnects and low-k dielectrics typically involves additional processing steps. For example, since copper may diffuse and introduce defects into semiconductor circuits, diffusion barriers may be required to prevent this diffusion. Application of diffusion barriers on low-k dielectrics is not without problems, however. Low-k dielectrics are frequently porous and this porosity may allow diffusion barrier materials to penetrate the porous dielectric, degrading the k value and/or other properties of the dielectric. Furthermore, diffusion barriers can occupy a significant fraction of the space available for the copper interconnects.

### BRIEF DESCRIPTION OF THE DRAWINGS

Some embodiments of the present invention are illustrated, by way of example and not limitation, in the accompanying figures, in which like references indicate similar elements and in which:

FIG. 1 is a flow chart illustrating a method for semiconductor wafer processing according to an embodiment of the present invention, wherein a porous low-k dielectric is sealed.

FIGS. 2A-D illustrate a semiconductor wafer processed according to an embodiment of the present invention, wherein a porous low-k dielectric is sealed.

FIGS. 3A-C illustrate a semiconductor wafer processed according to an embodiment of the present invention, wherein a sealed porous low-k dielectric is further processed by removing sealing compound from the surface.

FIGS. 4A-B illustrate a semiconductor wafer processed according to an embodiment of the present invention, wherein a sealed porous low-k dielectric is further processed without removing sealing compound from the surface.

FIG. 5 illustrates a semiconductor wafer processed according to an embodiment of the present invention, wherein a porous low-k dielectric is sealed with a conductive diffusion barrier and further processed without removing sealing compound from the surface.

FIG. 6 illustrates a microelectronic assembly according to the present invention.

FIG. 7 illustrates a schematic of a computer system according to the present invention.

### DETAILED DESCRIPTION

Methods for sealing porous low-k dielectrics are described, comprising treating the porous low-k dielectrics by atomic layer deposition so as to seal the pores.

Note that in this description references to “one embodiment” or “an embodiment” mean that the feature being referred to is included in at least one embodiment of the present invention. Further, separate references to “one embodiment” or “an embodiment” in this description do not necessarily refer to the same embodiment. However, such embodiments are also not mutually exclusive unless so stated, and except as will be readily apparent to those skilled in the art from the description. For example, a feature, structure, act, etc. described in one embodiment may also be included in other embodiments. Thus, the present invention can include a variety of combinations and/or integrations of the embodiments described herein.

In the following description numerous specific details are set forth. However, it is understood that embodiments may be practiced without these specific details. It is also understood that the description of particular embodiments is not to be construed as limiting the disclosure to those embodiments. Well-known circuits, structures and techniques have not been shown in detail in order not to obscure the understanding of this description.

As used herein, the terms “wafer” or “semiconductor wafer” generally refer to slices of semiconductor crystal processed to form electronic components, may be in any stage of completion, and may have features, transistors, logic gates, interconnects, devices, etc. created thereon.

As used herein, the term “layer” generally refers to materials, structures, and/or devices created on a wafer. A layer may be continuous across a wafer, but need not be, possibly having openings, discontinuities, or gaps therein. For example, a layer may be applied uniformly across a wafer or may be applied only to some areas of a wafer.

There is a growing trend to use porous low-k dielectrics for the manufacture of electronic devices. In particular, high performance devices can benefit from the use of porous low-k dielectrics because these dielectrics reduce the RC constant of device interconnects. A disadvantage of porous low-k dielectrics arises from their porosity, however. Porous low-k dielectrics have pores and pore interconnections, and these can form interconnected pore structures which may allow materials to penetrate the dielectric. Materials such as solvents, water and wafer processing byproducts, having penetrated the dielectric, can alter its dielectric constant and/or other properties. Furthermore, materials applied in subsequent wafer processing steps can likewise penetrate the dielectric. Thus, for example, application of a diffusion barrier, used to prevent diffusion of copper into the semiconductor device, may affect the low-k dielectric it is applied to. Known methods of depositing diffusion barrier material can result in the deposition of diffusion barrier material within the dielectric.

The inventor has discovered that it is possible to seal porous low-k dielectrics by using atomic layer deposition (ALD) to deposit sealing compound in the interconnected pore structures of the dielectric. By choosing ALD reactants appropriate to the dielectric material, ALD of sealing compound clogs the interconnected pore structures by depositing at or near the surface of the dielectric, yet without depositing throughout the thickness of the dielectric layer. ALD reactants are chosen in part based on their size: it is desirable to choose an ALD reactant sized such that it does not deeply penetrate the interconnected pore structures of the dielectric.

Atomic layer deposition is a technique used in the manufacture of semiconductor wafers which involves chemical reaction and deposition of a desired compound on an object through sequential exposure of the object to two or more reactants. This process, also known as atomic layer epitaxy or atomic layer chemical vapor deposition, grows the desired compound an atomic layer at a time. Typically, it involves placing an object in a chamber or reaction vessel and exposing it to a first reactant, which is provided in a gas or vapor phase and has a chemical affinity for the object. Some of this first reactant then chemically reacts with the object. The chamber is then cleared of the first reactant through application of vacuum, sweeping with a purge gas, or similar means. Once the chamber is cleared of the first reactant, the object is then exposed to a second reactant, again in a gas or vapor phase. The second reactant reacts with any of the first reactant bound to the object, thereby forming the desired compound. The cycle of exposure to the first reactant, clearing the chamber, and exposure to the second reactant may be repeated thereafter if so desired. Furthermore, ALD using more than two reactants in sequence is also possible.

The inventor has discovered that it is possible to seal the pores of porous low-k dielectrics by using ALD reactants appropriate to the dielectric material. The appropriate ALD reactants will depend not only on their chemical properties, but on their physical properties as well. In particular, it is preferable to choose the ALD reactants based at least in part on their size and on the physical characteristics of the low-k dielectric, in addition to choosing those which have adequate chemical affinities for the porous low-k dielectric. Preferably, the interconnected pore structures of the dielectric are sealed with an ALD reactant which has a molecular size which is approximately equal to the size of an analytical solvent which diffuses at a rate of less than approximately 1E-7 cm²/s (0.0000001 square centimeters per second). This allows the ALD process to deposit sealing compound within the interconnected pore structures near the surface, yet without depositing sealing compound throughout the thickness of the dielectric layer.

Note that, in choosing an ALD reactant based on its molecular size, one may elect to choose a reactant which has one or more molecular dimensions or conformations approximately equal in size to the analytical solvent, but which does not have all molecular dimensions or conformations equal to that size. That is, it may be desirable to choose a reactant based on a two-dimensional molecular size. For example, in choosing a reactant which is essentially oblong, even if the long dimension is larger than the analytical solvent, if the short dimension is approximately equal in size to the analytical solvent, then the reactant may be an appropriate choice.

Physical characterization of porous low-k dielectrics can be done in a number of ways, for example, by measuring the rate of diffusion of a liquid through the dielectric. A preferred technique involves determining the diffusion coefficients of a range of analytical solvents diffusing through samples of the dielectric. The analytical solvents used should be non-reactive towards the dielectric and have known molecular sizes. A series of analytical solvents of increasing molecular size is applied until that solvent is found which just barely diffuses. Preferably, characterization of the porous low-k dielectric is continued until an analytical solvent is found which diffuses at less than approximately 1E-7 cm²/s.

An example of this characterization technique is the measurement of the rate of diffusion of toluene. A sample of porous low-k dielectric is prepared by applying a layer of porous low-k dielectric to a substrate and then applying a capping layer to the dielectric. Preferably, the porous low-k dielectric is applied to the substrate such that it will have characteristics similar to those found in actual use when manufacturing semiconductor devices. Preferably, the substrate and the capping layer are relatively impermeable to toluene and the capping layer is of a material and thickness that allows for visual observation of solvent diffusion through the dielectric.

For example, a sample can be prepared by applying a layer of porous low-k dielectric to a wafer of crystalline silicon and then capping the layer with silicon nitride using plasma enhanced chemical vapor deposition. The silicon nitride cap must be thick enough to prevent leakage of toluene. Other capping layers may be employed if they are thick enough to prevent leakage and transparent enough to allow observation of solvent diffusion through the sample. The wafer is cleaved by scribing along a crystallographic plane with a diamond scribe then fracturing along the scribe line, after which toluene diffusion through the sample is observed by applying liquid toluene to an edge of the sample and using a microscope to make observations through the silicon nitride cap.

The diffusion coefficient of toluene is determined by how long it takes the toluene to travel a known distance, using the classical diffusion law described by the equation:
l=2(Dt/π)^{1/2}
where l is the diffusion length, D is the diffusion coefficient and t is time. Toluene may diffuse rapidly, for example at greater than 1E-5 cm²/s, or it may diffuse much more slowly, for example at less than 1E-7 cm²/s.

By measuring the diffusion rate of a series of analytical solvents until a solvent is found which exhibits a low diffusion rate through the porous low-k dielectric, one can estimate the size of the preferred ALD reactant based on the molecular size of that solvent: one should choose an ALD reactant which has a molecular size which is approximately equal to the size of a solvent which diffuses at a rate of less than approximately 1E-7 cm²/s.

For the example mentioned above, a dielectric exhibiting a toluene diffusion rate of 1E-7 cm²/s or less suggests that it would be appropriate to seal that dielectric by choosing an ALD reactant which has a molecular size approximately equal to toluene (0.67 nm). If not already known from the literature, the size of the ALD reactant can be determined through molecular modeling studies, such as those performed using Gaussian™ modeling software. As noted above, an ALD reactant may have molecular dimensions or conformations which differ, for example with an ALD reactant that is essentially oblong. In such a case, it is preferable to establish the size(s) of all dimensions and/or likely conformations during modeling.

It is important to note that solvent diffusion characterization of the porous low-k dielectric and Gaussian™ modeling of the ALD reactant are preferably used in addition to, rather than in lieu of, traditional approaches for choosing ALD reactants. Thus, it is preferable to combine solvent diffusion information with knowledge of the chemical affinity of the ALD reactant for the porous low-k dielectric.

Empirical studies can help further refine the choice of ALD reactants by providing information about the depth of penetration of the sealing compound after treatment of the dielectric by ALD. For example, if empirical X-ray reflectometry (XRR) studies show the ALD-deposited sealing compound is present at too great a depth in the dielectric, then it may be desirable to choose a larger ALD reactant or to choose an ALD reactant with a greater chemical affinity for the dielectric.

The sealing compound produced by the ALD process should not only seal the low-k dielectric, it should also be compatible with subsequent processing steps and not make the low-k dielectric unsuitable for its intended purpose. An example of a sealing compound is silicon dioxide, which has a k value of approximately 4.

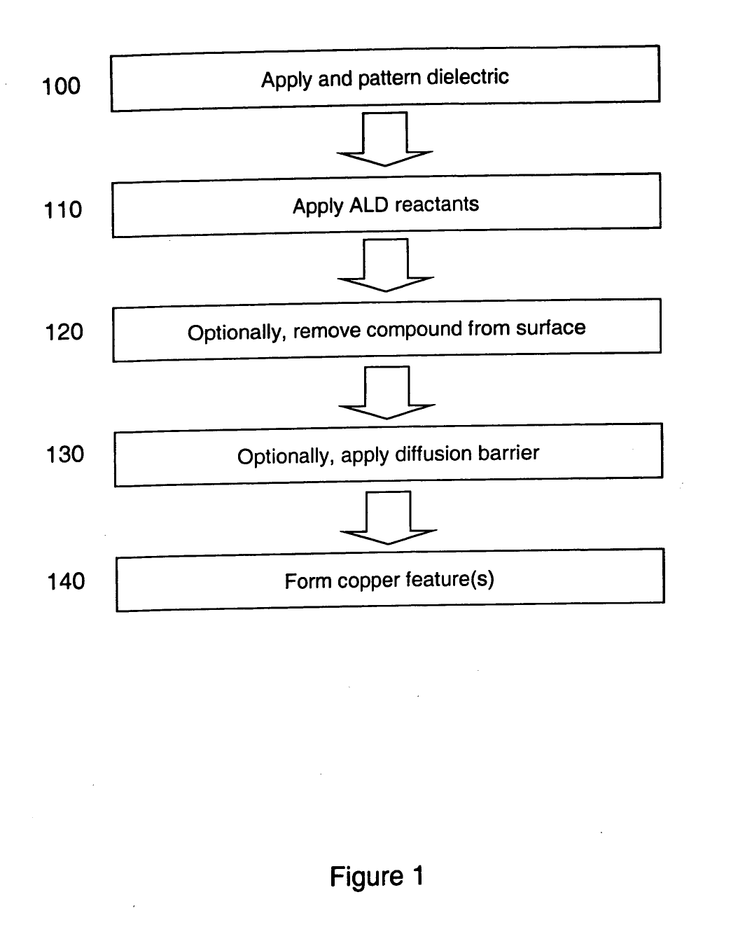

FIG. 1 is a flow chart illustrating a method for semiconductor wafer processing according to an embodiment of the present invention, wherein a porous low-k dielectric is sealed. In Block 100, a porous low-k dielectric layer is applied to a semiconductor wafer, and a feature or features are created therein. Features in the dielectric may include contacts, vias or trenches for interconnects formed by the damascene process. For example, a porous low-k dielectric layer may be formed by applying a dielectric to the wafer by chemical vapor deposition. The porous low-k dielectric may then be patterned and developed through traditional means to create a feature or features.

In Block 110, the semiconductor wafer is processed to seal the pores of the porous low-k dielectric. ALD is used to sequentially apply reactants in an ALD chamber. The semiconductor wafer is treated with a first reactant which has a size approximately equal to that of an analytical solvent which diffuses at a rate of less than approximately 1E-7 cm²/s. The reactant may be, for example, hexamethyldisiloxane (HMDS). The first reactant is supplied in a gas phase either alone or with a carrier. The first reactant is allowed sufficient time to fully envelop the semiconductor wafer and the feature(s) previously created in the porous low-k dielectric in Block 100. The first reactant binds to active sites on the dielectric, including those on the surface of the dielectric and those within the interconnected pore structures near the surface. In part because its size is appropriate for the dielectric being treated, the first reactant does not deeply penetrate the dielectric, instead binding to sites on the surface and within the interconnected pore structures near the surface.

After the application of the first reactant to the semiconductor wafer, the ALD chamber is cleared of the first reactant through means of vacuum, purge gas or other appropriate techniques. The semiconductor wafer is then treated with a second reactant. The second reactant may be, for example, water. The second reactant, supplied in a gas phase either alone or with a carrier, is allowed to fully envelop the semiconductor wafer and the feature(s) previously created in the porous low-k dielectric. The second reactant reacts with bound first reactant molecules to form the sealing compound. The sealing compound may be, for example, silicon dioxide.

The sealing compound formed according to this embodiment of the present invention acts to seal the pores of the low-k dielectric without permeating it. Sealing compound is formed anywhere the second reactant encounters bound first reactant. Thus, sealing compound is formed on the surface and within the interconnected pore structures near the surface of the dielectric. Since the sealing compound formed within the interconnected pore structures in this manner acts to seal the pores by limiting the access of subsequent materials to those pores, it helps prevent degradation of the k value and other properties of the dielectric due to intrusion of materials in the interconnected pore structures.

It may be necessary or desirable to repeat the ALD cycle of applying first reactant, purging, and applying second reactant in order to increase the amount of sealing compound deposited within the interconnected pore structures near the surface of the low-k dielectric. Preferably, the ALD process is continued until the low-k dielectric is sufficiently sealed that materials encountered in subsequent processing steps are unable to enter the dielectric.

In Block 120, sealing compound is optionally removed from the surface of the low-k dielectric, leaving behind sealing compound in the interconnected pore structures near the surface and thus maintaining the sealing of the dielectric. For example, silicon dioxide may be removed from the bottom of vias to allow for electrical connection between conductors.

In Block 130, a diffusion barrier is optionally applied to prevent copper, applied in a subsequent step, from diffusing into the semiconductor device. The diffusion barrier may be, for example, a tantalum- or tungsten-containing material. Sealing the low-k dielectric according to this embodiment of the present invention helps prevent undesirable diffusion barrier material penetration into the dielectric and helps reduce the deleterious effects of that penetration on the electrical properties of the dielectric layer. Furthermore, an effective diffusion barrier may be obtained with a thinner application of diffusion barrier material than is possible using other processes known in the art. This helps maximize the feature dimensions available for copper traces.

In Block 140, copper is applied to the semiconductor wafer to form a copper feature. For example, if the semiconductor wafer is processed by the damascene process, copper features may be formed in those features which were previously formed in the dielectric in Block 100. Such features may be, for example, vias or interconnects.

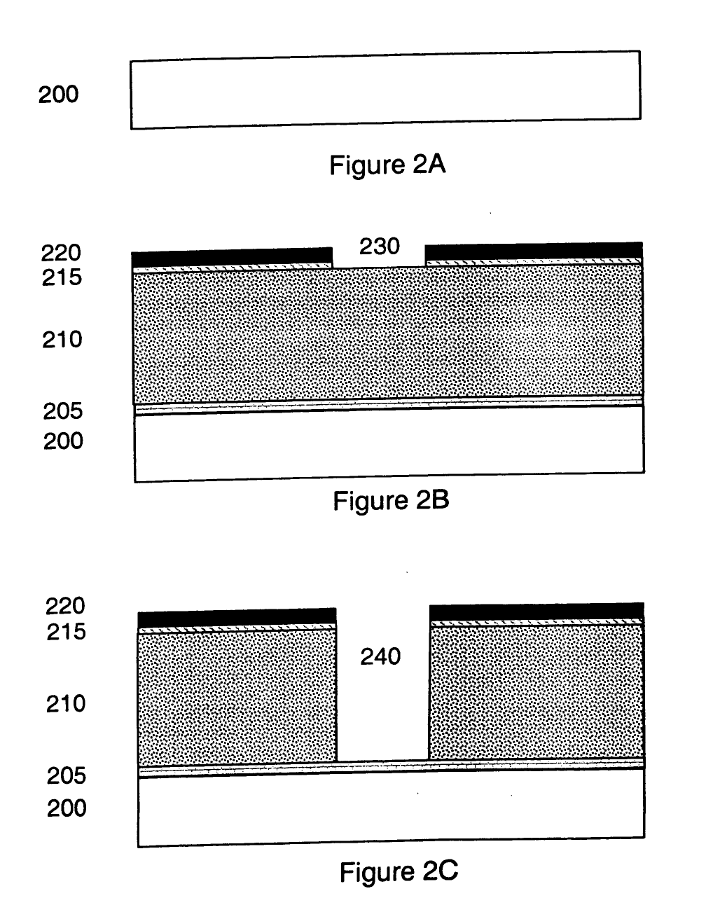

FIGS. 2A-D illustrate a semiconductor wafer processed according to an embodiment of the present invention, wherein a porous low-k dielectric is sealed.

In FIG. 2A, a semiconductor wafer 200 is shown. Wafer 200 may have numerous layers and/or devices created thereon.

FIG. 2B illustrates wafer 200 after application of an etch stop layer 205, a porous low-k dielectric layer 210, and a hardmask layer 215, followed by applying, masking, exposing, and developing a photoresist layer 220 to create an opening 230. Opening 230 will allow an etch process to create a feature at that point.

FIG. 2C illustrates wafer 200 after etching porous low-k dielectric layer 210. Etching creates a feature 240 in low-k dielectric layer 210. Feature 240 may be, for example, a trench created in the damascene method of wafer processing.

FIG. 2D illustrates wafer 200 after removal of photoresist layer 220 followed by atomic layer deposition of a sealing compound. In this embodiment, a first ALD reactant is chosen that has a molecular size which is approximately equal to the size of an analytical solvent which diffuses through a representative sample of low-k dielectric at a rate of less than approximately 1E-7 cm²/s.

The ALD reaction deposits sealing compound on hardmask 215 and exposed surfaces 250 and within the interconnected pore structures 255 near the surface, but not throughout the thickness, of low-k dielectric 210, thus sealing low-k dielectric 210 without excessive degradation of its k value or other properties. In an embodiment, ALD using HMDS and water deposits silicon dioxide hardmask 215 and exposed surfaces 250 and within the interconnected pore structures 255 near the surface of low-k dielectric 210. Wafer 200 is shown with a build up of ALD-deposited sealing compound on the surface of hardmask 215 and the surface of etch stop 205 at the bottom of feature 240; since ALD results in the deposition of sealing compound on any surfaces which are reactive toward the ALD reactants, sealing compound will deposit on exposed surfaces if those areas are reactive.

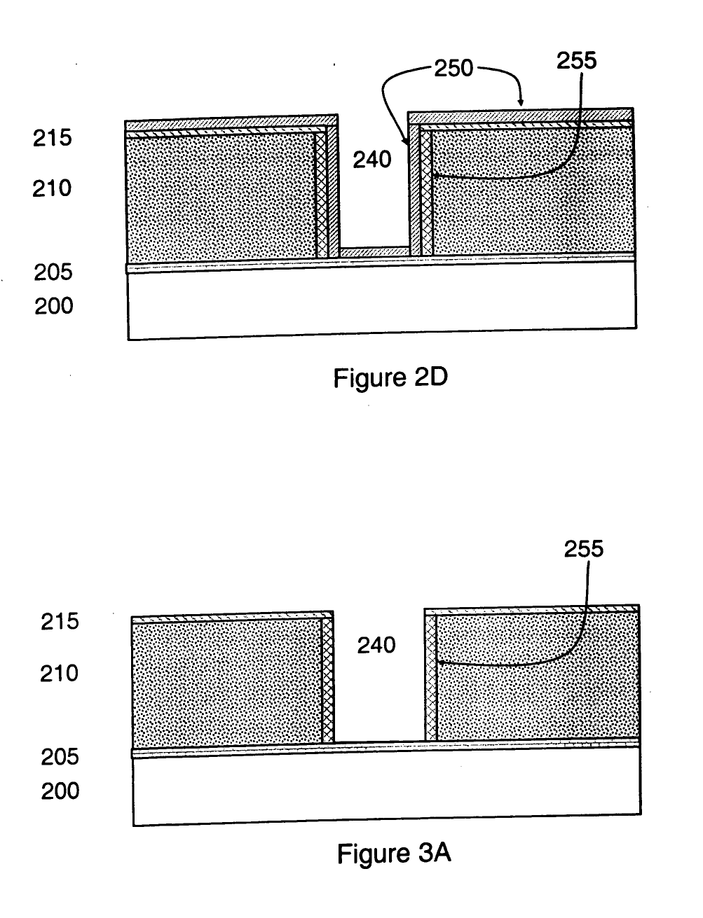

FIGS. 3A-C illustrate a semiconductor wafer processed according to an embodiment of the present invention, wherein a sealed low-k dielectric is further processed by removing sealing compound from the surface.

FIG. 3A illustrates the wafer 200 of FIG. 2D after removal of ALD-deposited compound from hardmask 215, surfaces 250 of low-k dielectric 210, and etch stop 205 at the bottom of feature 240. Removal may be, for example, by an etch process. Sealing compound remains within the interconnected pore structures 255 near the surfaces of low-k dielectric 210. In another embodiment, removal of etch stop 205 at the bottom of feature 240 may be effected at the same time as the removal of ALD-deposited material from the surfaces 250. For example, removal of ALD-deposited material may be integrated with an etch stop removal process for creation of a contact or via.

FIG. 3B illustrates wafer 200 after application of a diffusion barrier 260. Notably, sealing compound within the interconnected pore structures 255 near the surface of low-k dielectric 210 helps prevent diffusion barrier 260 from penetrating low-k dielectric 210. Thus, sealing the porous surface of low-k dielectric 210 according to this embodiment of the present invention helps prevent the deleterious effects of penetration of diffusion barrier 260 into low-k dielectric 210. Furthermore, sealing the porous surface of low-k dielectric 210 according to this embodiment of the present invention may allow for application of a thinner diffusion barrier 260 than would be effective under previously known processes, since known processes may require a thick barrier to form a continuous, impermeable diffusion barrier on a porous low-k dielectric.

FIG. 3C illustrates wafer 200 after application of copper in feature 240 to form copper feature 270. Copper feature 270 may be, for example, a damascene trench.

Optionally, a damascene via or contact may be formed, in which diffusion barrier 260 and etch stop 205 are removed from the bottom of feature 240 by etching, prior to application of copper. Since sealing compound within the interconnected pore structures 255 seals the dielectric, no sealing compound is required on the surface of the dielectric layer. Thus, etching can be employed at this stage.

In contrast, known methods of sealing dielectric layers, which act through application of surface treatments but do not penetrate the interconnected pore structures near the surface, are incompatible with etching because the surface treatment is susceptible to removal by the etch process used to open the damascene via or contact. Thus, an etchback step to open damascene trenches/vias after barrier deposition but before copper deposition will destroy the sealing layer created by known processes.

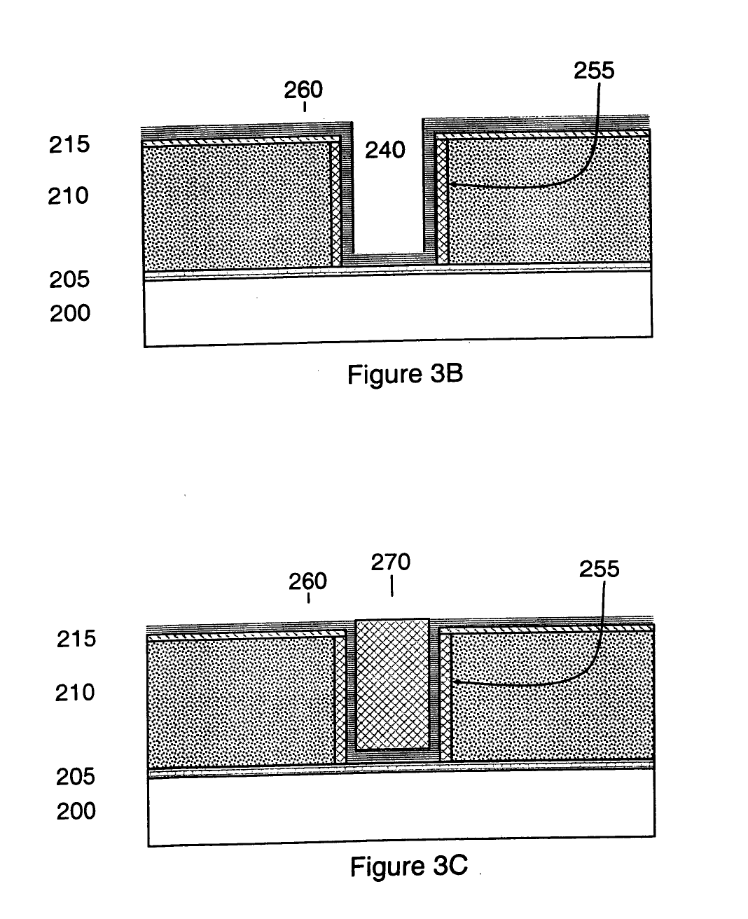

FIGS. 4A-B illustrate a semiconductor wafer processed according to an embodiment of the present invention, wherein a sealed porous low-k dielectric is further processed without removing sealing compound from the surface.

FIG. 4A illustrates the wafer 200 of FIG. 2D after application of a diffusion barrier 260. In contrast to the method illustrated in FIG. 3A, sealing compound on hardmask 215 and surface 250 of the porous low-k dielectric is not removed. Sealing compound on surface 250 and within the interconnected pore structures 255 near the surface of porous low-k dielectric 210 helps prevent diffusion barrier 260 from penetrating porous low-k dielectric 210. Thus, sealing the porous surface of low-k dielectric 210 according to this embodiment of the present invention helps prevent the deleterious effects of penetration of diffusion barrier 260 into porous low-k dielectric 210. Furthermore, sealing the porous surface of low-k dielectric 210 according to this embodiment of the present invention may allow for application of a thinner diffusion barrier 260 than would be effective under previously known processes, since known processes may require a thick barrier to form a continuous, impermeable diffusion barrier on a porous low-k dielectric.

FIG. 4B illustrates wafer 200 after application of copper in feature 240 to form copper feature 270. Copper feature 270 may be, for example, a damascene trench.

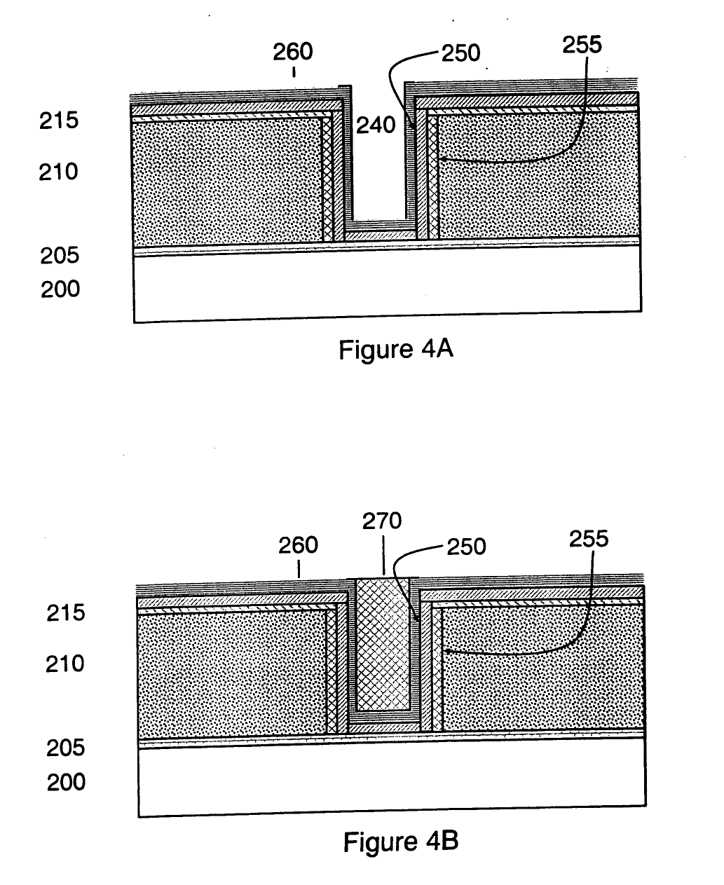

Optionally, as illustrated in the embodiment shown in FIG. 5, other processes may be employed in which via or contact etch precedes dielectric sealing. ALD reactants may then be chosen which seal the interconnected pore structures with a sealing compound having both diffusion barrier and conductive properties. In this case, copper feature 280 deposited after pore sealing, and without removal of sealing compound 250 from the surface of the porous low-k dielectric, may be placed in electrical contact with underlying layer 200. Copper feature 280 may be, for example, a via or contact. Since sealing compound is not deposited throughout the thickness of the dielectric layer, the potentially deleterious effects a conductive compound might have on the dielectric properties are reduced, and may be offset by the advantages realized by elimination of one or more processing steps.

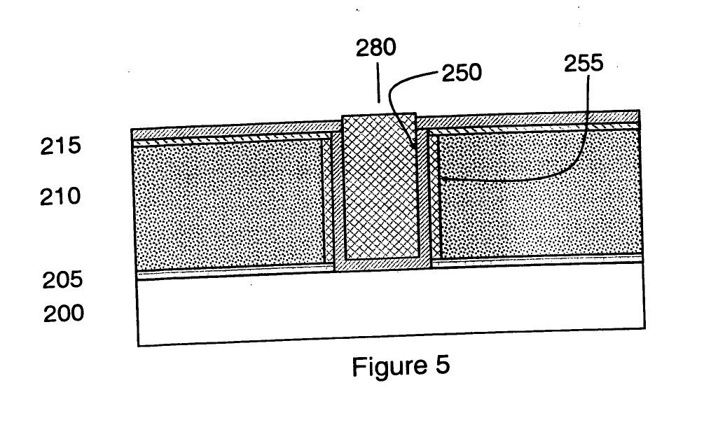

FIG. 6 illustrates a microelectronic assembly 600 according to the present invention. Microelectronic assembly 600 comprises one or more semiconductor devices formed by the present invention, such as a device formed from a semiconductor wafer according to FIG. 3C. The device or devices may be bonded to a substrate and are housed in a package 610 with connectors 620. Connectors 620 may be, for example, an array of solder bumps.

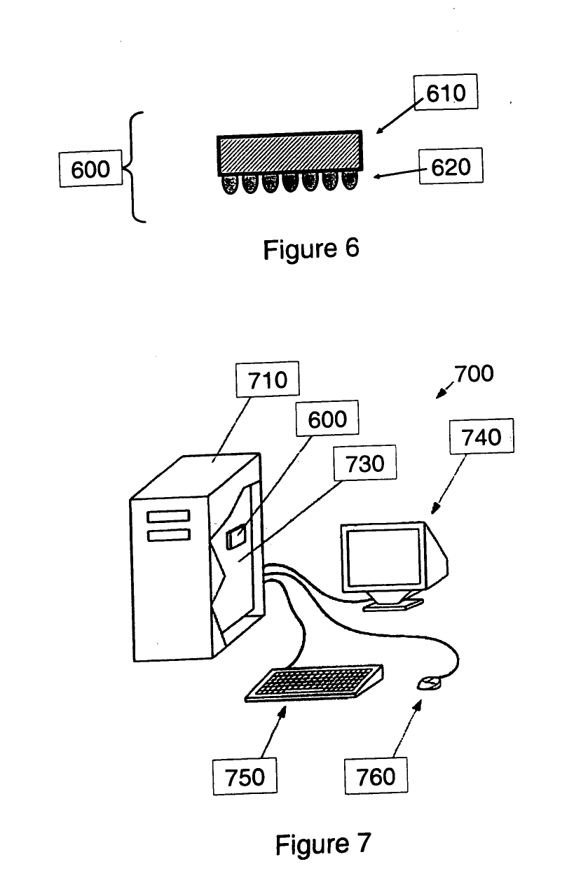

FIG. 7 illustrates a schematic of a computer system 700 according to the present invention. The microelectronic packages formed by the present invention, such as microelectronic assembly 600 of FIG. 5, may be used in a computer system 700, as shown in FIG. 6. The computer system 700 may comprise a motherboard 730 with the microelectronic assembly 600 connected thereto, within a chassis 710. The motherboard 730 may be attached to various peripheral devices including a keyboard 750, a mouse 760, and a monitor 740.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A semiconductor device comprising:
a porous dielectric layer; and
a compound;
wherein the compound is formed in interconnected pore structures near a surface of the dielectric layer and not throughout the thickness of the dielectric layer.

2. The device of claim 1, wherein the compound is silicon dioxide.

3. The device of claim 1, further comprising a diffusion barrier, the diffusion barrier applied after removing compound from the surface.

4. The device of claim 1, wherein the compound is electrically conductive.

5. The device of claim 4, further comprising copper applied to the compound.

6. A computer system, comprising:
a motherboard;
a semiconductor device electrically connected to the motherboard, the device comprising a porous dielectric layer and a compound;
wherein the compound is formed in interconnected pore structures near a surface of the dielectric and not throughout the thickness of the dielectric layer.

7. The system of claim 6, wherein the compound is silicon dioxide.

8. The system of claim 6, further comprising a diffusion barrier, the diffusion barrier applied after removing compound from the surface.

9. The system of claim 6, wherein the compound is electrically conductive.

10. The system of claim 9, further comprising copper applied to the compound.
